(19) United States
(12) Patent Application Publication
(10) Pub. No.: US 2006/0260673 A1
(43) Pub. Date: Nov. 23, 2006

(54) Photovoltaic element and method of producing photovoltaic element

(75) Inventor: Yoshifumi Takeyama, Tokyo (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/569,203

(22) PCT Filed: Oct. 15, 2004
(86) PCT No.: PCT/JP04/15658

§ 371 Date: Feb. 23, 2006

(30) Foreign Application Priority Data
Oct. 17, 2003 (JP) 2003-357778

(51) Int. Cl. H01L 31/00

(52) U.S. Cl. 136/252

(57) ABSTRACT

A photovoltaic element is provided which has at least a photovoltaic layer and a transparent electrode layer deposited on a metal substrate, a portion of the transparent electrode layer being continuously removed at a peripheral part of the metal substrate, wherein an island-shaped transparent-electrode-layer-removed-portion is provided in the transparent electrode layer in a power-generating region surrounded by the removed portion of the transparent electrode layer, a rear surface side bus-bar electrode electrically connected to the metal substrate is disposed on the rear surface side of the metal substrate at the rear of the island-shaped transparent-electrode-layer-removed-portion, and the rear surface side bus-bar electrode is connected to the metal substrate at a portion corresponding to the island-shaped transparent-electrode-layer-removed-portion, and which can enhance the degree of freedom for the shape of a photovoltaic element module while ensuring the reliability of the photovoltaic element.

### TECHNICAL FIELD

The present invention relates to a photovoltaic element used in a solar cell and a photoelectronic sensor, and particularly relates to a photovoltaic element having a rear surface side bus-bar electrode for taking out an electric power installed on a metal substrate having a semiconductor layer deposited thereon.

### BACKGROUND ART

In recent years, a green house effect, namely, a global warming caused by an increase of CO₂ becomes a subject of discussion, so that there is an increasing demand for development of a clean energy source which does not exhaust CO₂. There is nuclear power generation as one of such energy sources, but it has many problems to be solved such as radioactive waste, and there is an increasing demand for a clean energy source having a higher degree of safety.

Under the circumstances, a solar cell, among clean energy sources expected for the future, receives special attention in terms of cleanliness, a high degree of safety, and handlability.

Now, many solar cells are proposed, and some of them are really used as a power source. Such a solar cell is broadly classified into a crystalline silicon solar cell using monocrystalline silicon or polycrystalline silicon, an amorphous silicon solar cell using amorphous silicon, and a compound semiconductor solar cell.

A representative structure of a photovoltaic element is constituted by a semiconductor layer with a p-n junction, a light-receiving surface electrode formed of a transparent conductive oxide on the light-receiving surface of the semiconductor layer, a current-collecting electrode made of a comparatively thin metal for collecting an electric current, and further an electrode made of a comparatively thick metal, called a bus bar, for collecting the electric current collected by the above described current-collecting electrode formed thereon.

As for an electrode structure of a photovoltaic element, an invention that employs an electrode made of a metal wire coated with a polymer containing electroconductive particles is disclosed in U.S. Pat. No. 4,260,429. The electrode of the invention employs the metal wire such as of copper with a high electroconductivity, consequently has a little electric resistance loss even when forming a long current-collecting electrode, and can lower a shadow loss because the aspect ratio can be adjusted to 1:1. Further, the electrode of the invention has uniqueness capable of being bonded by simple thermocompression bonding with the use of an electroconductive adhesive in order to fix the wire.

The present inventor has improved the above described current-collecting electrode using the metal wire, and proposed an electrode structure of a photovoltaic element such as disclosed in Japanese Patent Application Laid-Open No. H7-321353, Japanese Patent Application Laid-Open No. H9-018034 and Japanese Patent Application Laid-Open No. H10-065192.

Further, as for a rear surface electrode opposing the above described current-collecting electrode, an invention directed to an electrode structure having a bus-bar electrode arranged on the rear surface of a metal substrate of a photovoltaic element is disclosed in Japanese Patent Application Laid-Open No. H3-239375. In the invention, because a bus-bar electrode having a lower specific resisitivity than that of a stainless steel is arranged on a non-light-receiving surface of a photovoltaic element using a stainless steel substrate, an electrode structure with a low electric resistance loss can be realized.

The present inventor has improved an electrode on a non-light-receiving surface side using the above described bus-bar electrode on the rear surface of the metal substrate, and proposed an electrode structure of a photovoltaic element such as disclosed in Japanese Patent Application Laid-Open No. H8-139349 and Japanese Patent Application Laid-Open No. H11-77348.

An example of a method of forming the electrode of a photovoltaic element is described with reference to FIGS. 7A and 7B. FIGS. 7A and 7B are schematic views showing the structure of the photovoltaic element provided with a current-collecting electrode using a metal wire. FIG. 7A is a schematic view of the photovoltaic element viewed from a light-receiving surface side, and FIG. 7B is a schematic view viewed from a non-light-receiving surface side.

In FIGS. 7A and 7B, 501 denotes a photovoltaic element plate of a 200 mm×250 mm size before electrode formation, which has three layers of a bottom electrode layer, an amorphous silicon layer having a photovoltaic function and a transparent electrode layer provided on a substrate.

A method of producing a photovoltaic element plate 501 comprises firstly sequentially depositing Al and ZnO using a sputtering method right on a stainless steel sheet for supporting the whole photovoltaic element plate to form a bottom electrode layer. Then, the amorphous silicon layer is formed by sequentially depositing n-type, i-type, p-type, n-type, i-type and p-type layers in the mentioned order from a substrate side by a plasma CVD method. Further, the transparent electrode layer is a transparent electrode film formed by vapor depositing In in an O₂ atmosphere by resistive heating to form an indium oxide thin film.

The method further comprises, in order to prevent a short circuit occurring between the stainless steel sheet and the transparent electrode film when cutting the photovoltaic element plate 501 from detrimentally affecting an effective light-receiving range, applying an etching paste containing FeCl₃, AlCl₃, and the like on the transparent electrode film by a screen printing method and then effecting heating and cleaning, thereby removing the transparent electrode film at the outer periphery of a power-generating region surrounded by three sides of the periphery of the photovoltaic element plate 501 and a bus-bar electrode described later in a linear form to form an etching line 502.

The method further comprises subsequently disposing a rear surface side bus-bar electrode 503 on a non-light-receiving surface of a region for provision of a bus-bar electrode thereon, which is separated from the power-generating region by the etching line 502 of the photovoltaic element plate 501, and connecting the photovoltaic element plate 501 to the rear surface side bus-bar electrode 503 in the non-power-generating region. The connection is carried out by employing a method disclosed in Japanese Patent Application Laid-Open No. H8-139349.

The method further comprises subsequently applying an insulation member 504 for a bus-bar electrode, which is mainly made of polyimide and coated with an adhesive on both side thereof, on a region for provision of the bus-bar electrode of the photovoltaic element plate 501 thereon. Then, conductive-adhesive-coated metallic wire members 505 formed by previously coating metallic wires with an electorconductive adhesive containing a carbon paste are disposed at equal intervals continuously on the photovoltaic element plate 501 and the insulation member 504 for the bus-bar electrode, thereby making current-collecting electrodes. Further, a bus-bar electrode 506 for collecting the electric current of the current-collecting electrodes is formed on the top of the insulation member 504 for the bus-bar electrode and then heated and pressurized to be fixed thereon.

Because the photovoltaic element 500 produced by the above described method has low voltage-current characteristics in a single unit, in order to make a system for outputting 6V or 12V for instance, a plurality of the photovoltaic elements are connected in series or in parallel to provide a photovoltaic element module.

Referring to FIG. 8, a photovoltaic element module will be now explained which connects the above described photovoltaic elements 500 in series. FIG. 8 is a schematic view of the photovoltaic element module having three photovoltaic elements connected in series, when viewed from the light-receiving surface side. A bus-bar electrode 506 of the photovoltaic element 500 is routed to the non-light-receiving surface side of the adjacent photovoltaic element 500 and is electrically connected to the rear surface side bus-bar electrode 503. Thus, the shape of the photovoltaic element 500 is of such a structure as to enable a plurality of the photovoltaic elements to be easily connected in series or in parallel.

To the photovoltaic element module, various sizes and designs are required depending on installation geometry. However, the standard dimension of a photovoltaic element and the standard dimension of a photovoltaic element module as required are not always in a multiple relation. As a result, the light-receiving surface of the photovoltaic element module cannot always be filled with photovoltaic elements without leaving a gap to be utilized effectively. On the other hand, the standard dimension of a photovoltaic element is increasingly enlarged in order to reduce the production cost, which increasingly enlarges odd gaps incapable of disposing the photovoltaic element therein, thus making it difficult to effectively utilize the light-receiving surface area.

In order to fit a large-area photovoltaic element to as various dimensions of photovoltaic element modules as possible, there is a method of forming the shape of the photovoltaic element to a rectangle. The forms described above for the prior art are typical ones, which can cope with various widths of the photovoltaic element modules by selecting either a longitudinal direction or a lateral direction of a rectangle for the series direction of the photovoltaic elements, thereby enhancing the freedom of designing.

In such a photovoltaic element of a rectangular shape, current-collecting electrodes are provided parallel to the widthwise direction in most cases. This is because a material constituting a current-collecting electrode of a photovoltaic element does have some finite resistance value, and as a result, the resistance loss increases with the increasing length of the current-collecting electrode. If the width of the current-collecting electrode is expanded, the resistance loss is decreased, but then the expanded width increases the shadow loss in turn. After all, it is advantageous to provide the current-collecting electrodes in the widthwise direction.

The present inventor, in contemplation of the above described background, has intensively studied as to what configuration of an electrode enables photovoltaic elements of a rectangular shape to be connected in series not only in a longitudinal direction as shown in FIG. 8 but also in a widthwise direction, while keeping a current-collecting electrode placed in the widthwise direction. As a result, the present inventor has reached a conclusion that the configuration as shown in FIGS. 10A and 10B was preferable. Specifically, by providing a bus-bar electrode on the rear surface of the photovoltaic element so as to be offset with respect to a bus-bar electrode provided on the front surface, series connection in the widthwise direction becomes easy as shown in FIG. 9.

However, it has been found that because such electrode configuration makes a bus-bar electrode provided on the rear surface be positioned in the rear surface of the power-generating region of a photovoltaic element, if the rear surface side bus-bar electrode is connected by some working in such a state, there is posed a problem that the element in the power-generating region may be deteriorated or broken.

### DISCLOSURE OF THE INVENTION

According to a first aspect of the present invention, there is provided, as a measure for solving the above described problems, a photovoltaic element having at least a photovoltaic layer and a transparent electrode layer deposited on a metal substrate, a portion of the transparent electrode layer being continuously removed at a peripheral part of the metal substrate, wherein an island-shaped transparent-electrode-layer-removed-portion is provided in the transparent electrode layer in a power-generating region surrounded by the removed portion of the transparent electrode layer, a rear surface side bus-bar electrode electrically connected to the metal substrate is disposed on the rear surface side of the metal substrate at the rear of the island-shaped transparent-electrode-layer-removed-portion, and the rear surface side bus-bar electrode is connected to the metal substrate at a portion corresponding to the island-shaped transparent-electrode-layer-removed-portion.

In the present invention, it is preferred that the island-shaped transparent-electrode-layer-removed-portion is separate from the removed portion of the transparent electrode layer that surrounds the power-generating region.

Further, it is preferred that the island-shaped transparent-electrode-layer-removed-portion is integrated with the removed portion of the transparent electrode layer that surrounds the power-generating region.

Moreover, it is preferred that a current-collecting electrode is disposed through an insulating member on the island-shaped transparent-electrode-layer-removed-portion just over the portion where the rear surface side bus-bar electrode and the metal substrate are connected to each other.

Further, it is preferred that a plurality of current-collecting electrodes are provided on the transparent electrode layer, and the island-shaped transparent-electrode-layer-removed-portion just over the portion where the rear surface side bus-bar electrode and the metal substrate are connected to each other is arranged between the current-collecting electrodes.

According to a second aspect of the present invention, there is provided, as a measure for solving the above-described problems, a method of producing a photovoltaic element having at least a photovoltaic layer and a transparent electrode layer deposited on a metal substrate, a portion of the transparent electrode layer being continuously removed at a peripheral part of the metal substrate, the method comprising the steps of:

providing an etching line in the photovoltaic element;

providing an island-shaped transparent-electrode-layer-removed-portion in the transparent electrode layer in a region surrounded by the etching line in the photovoltaic element; and

disposing a rear surface side bus-bar electrode on the rear surface side of the metal substrate at the rear of the island-shaped transparent-electrode-layer-removed-portion and connecting the rear surface side bus-bar electrode to the metal substrate at a portion corresponding to the island-shaped transparent-electrode-layer-removed-portion.

In the present invention, it is preferred that the step of providing the etching line in the photovoltaic element and the step of providing the island-shaped transparent-electrode-layer-removed-portion are carried out in the same step.

Further, it is preferred that the step of providing the etching line in the photovoltaic element and the step of providing the island-shaped transparent-electrode-layer-removed-portion are carried out separately from each other.

Moreover, it is preferred that at least the step of providing the island-shaped transparent-electrode-layer-removed-portion is carried out prior to the step of connecting the rear surface side bus-bar electrode to the metal substrate.

Further, it is preferred that at least the step of connecting the rear surface side bus-bar electrode to the metal substrate is carried out prior to the step of providing the island-shaped transparent-electrode-layer-removed-portion.

According to the present invention, by connecting the rear surface side bus-bar electrode to the metal substrate at a portion corresponding to the island-shaped transparent-electrode-layer-removed-portion, only a region in which the semiconductor element may be deteriorated due to connection working of the rear surface side bus-bar electrode can be electrically separated from the transparent electrode layer in the other portion of the power-generating region (the region surrounded by the etching line in which the peripheral portion of the transparent electrode layer is continuously removed), so that the reliability of the photovoltaic element can be ensured. As a result, when in order to facilitate series connection in a widthwise direction of the photovoltaic elements, the rear surface side bus-bar electrode is disposed so as to be offset in a lateral direction with respect to the bus-bar electrode provided on the surface of the photovoltaic element, there can be obtained a technical effect that the degree of freedom for the shape of a photovoltaic element module is enhanced while the reliability of the photovoltaic element is ensured.

Other features and advantages of the present invention will be apparent from the following description taken in conjunction with the accompanying drawings.

### BRIEF DESCRIPTION OF THE DRAWINGS

FIGS. 1A and 1B are schematic views for explaining a photovoltaic element according to Example 1 of the present invention;

FIG. 2 is a schematic view for explaining another form of an island-shaped transparent-electrode-layer-removed-portion according to Example 1 of the present invention;

FIG. 3 is a schematic view for explaining still another form of an island-shaped transparent-electrode-layer-removed-portion according to Example 1 of the present invention;

FIGS. 4A and 4B are schematic views for explaining a photovoltaic element before being divided, according to Example 2 of the present invention;

FIGS. 5A and 5B are schematic views for explaining the photovoltaic element after being divided, according to Example 2 of the present invention;

FIG. 6 is a schematic view showing the appearance of photovoltaic elements connected in series in a widthwise direction after being divided, according to Example 2 of the present invention;

FIGS. 7A and 7B are schematic views for explaining a conventional photovoltaic element;

FIG. 8 is a schematic view for explaining a structure of rectangular photovoltaic elements connected in series in a longitudinal direction;

FIG. 9 is a schematic view for explaining a structure of rectangular photovoltaic elements connected in series in a widthwise direction;

FIGS. 10A and 10B are schematic views for explaining a structure in which a rear surface side bus-bar electrode is disposed so as to be offset with respect to a bus-bar electrode provided on the front surface of a photovoltaic element; and

FIGS. 11A and 11B are schematic views for explaining an embodiment according to the present invention.

### BEST MODE FOR CARRYING OUT THE INVENTION

Embodiments according to the present invention will be now described with reference to the attached drawings. In the respective FIGURES, like numerals denote like elements.

FIGS. 11A and 11B are schematic views for explaining an example of a photovoltaic element according to the present invention. FIG. 11A is a schematic view of the photovoltaic element when viewed from a light-receiving surface side, and FIG. 11B is a schematic view when viewed from a non-light-receiving surface side.

In FIGS. 11A and 11B, 901 denotes a photovoltaic element plate. In order that short circuiting between a substrate and a transparent electrode film occurring when the periphery of the photovoltaic element plate 901 is cut does not exert an adverse effect on a power-generating region, a portion of a transparent electrode film at the periphery of the photovoltaic element plate 901 is removed in a linear form to form an etching line 902. Furthermore, an island-shaped transparent-electrode-layer-removed-portion 907 is formed in a region corresponding to a connection portion of a rear surface side bus-bar electrode, and subsequently, the rear surface side bus-bar electrode 903 is provided on the non-light-receiving surface side of the photovoltaic element plate 901. Thereby, in the island-shaped transparent-electrode-layer-removed-portion 907, the connection portion of the rear surface side bus-bar electrode 903 to the photovoltaic element plate 901 is provided.

Subsequently, an insulation member 908 is disposed on the island-shaped transparent-electrode-layer-removed-portion 907, concurrently an insulation member 904 for a bus-bar electrode is disposed on the light-receiving surface side of the photovoltaic element plate 901, and current-collecting electrodes 905 are formed on the photovoltaic element plate 901, the insulation member 908 and the insulation member 904 for the bus-bar electrode. Furthermore, on the member 904 for a bus-bar electrode, a bus-bar electrode 906, which is an electrode for collecting a current further from the current-collecting electrodes, is formed.

[Photovoltaic Element]

The configuration of the photovoltaic element according to the present invention is preferably applicable to an amorphous silicon-based photovoltaic element with a metal substrate used for a photoelectronic sensor, a photodiode, a solar cell or the like. However, a similar configuration is also applicable to a photovoltaic element using a semiconductor other than the amorphous silicon, such as monocrystalline silicon or polycrystalline silicon, or a semiconductor other than a silicon based semiconductor such as a compound semiconductor or a Schottky junction semiconductor.

Members constituting the photovoltaic element used in the embodiments according to the present invention will be described below in detail.

(Substrate)

The substrate is a member for mechanically supporting a semiconductor layer in a photovoltaic element made of a thin film such as of SOI monocrystalline silicon or amorphous silicon, and is also used as an electrode. The substrate, though depending on the type of the photovoltaic element, may need to have such heat resistance as to endure heating when a semiconductor film is formed. Examples of the material for the substrate include a thin sheet of, for instance, a metal such as Fe, Ni, Cr, Al, Mo, Au, Nb, Ta, V, Ti, Pt, and Pb, or an alloy thereof, specifically brass or stainless steel; and a composite thereof.

(Lower Electrode Layer)

The lower electrode layer is one of the electrodes for collecting an electric power generated in a semiconductor layer, and needs to be in ohmic contact with a semiconductor layer or the like. Usable materials include, for instance, so-called an elemental metal, an alloy and a chemical compound, such as Al, Ag, Pt, Au, Ni, Ti, Mo, Fe, V, Cr, Cu, stainless steel, brass, nichrome, SnO₂, In₂O₃, ZnO, ITO (indium-tin-oxide) and a transparent conductive oxide (TCO); and an electroconductive paste containing the above described electroconductive materials. Further, when the lower electrode is to be provided on the non-light-receiving surface of a semiconductor layer, a surface of the lower electrode layer to be in contact with the semiconductor layer may be subjected to a texture treatment for causing irregular reflection of light.

As a method of producing a lower electrode layer, there may be employed a well-known method such as plating, vapor deposition, sputtering, or silk-screen printing. Further, when a substrate is used as a lower electrode, a lower electrode needs not to be provided separately.

(Semiconductor Layer)

As a material for the semiconductor layer, there can be used a well-known semiconductor material generally used as a photovoltaic element. Preferable examples of the semiconductor material used for the photovoltaic element of the present invention include a semiconductor of Group IV of the periodic table such as thin film monocrystalline silicon, thin film polycrystalline silicon and amorphous silicon, a Group II-VI semiconductor such as CdS and CdTe, and a Group III-V semiconductor such as GaAs. Further, not only a single cell but also a tandem cell having a plurality of p-i-n junctions or p-n junctions stacked, such as a triple cell, are preferably used. Furthermore, an organic semiconductor such as Schottky semiconductor or dye-sensitized semiconductor may also be used. As a method of producing the semiconductor layer, the amorphous silicon type semiconductor layer can be produced by introducing a source gas such as silane gas for thin film formation, into a plasma CVD apparatus that generates a plasma discharge. Further, the GaAs type compound semiconductor layer is formed by a method such as' electron-beam evaporation method, sputtering method or electrodeposition method. The thin film monocrystalline silicon may be produced by a SOI method or the like.

(Transparent Electrode Layer)

The transparent electrode layer is the other electrode for collecting an electric power generated in the semiconductor layer, and makes a pair with the lower electrode layer. The transparent electrode layer is necessary for a semiconductor with a high sheet resistivity such as amorphous silicon semiconductor, but may not be particularly necessary for a crystalline semiconductor or the like because of having a low sheet resistivity. Further, because the transparent electrode layer is located on the light incidence side, it needs to be transparent and is occasionally called a transparent electrode. The transparent electrode layer preferably has a light transmittance of 85% or more, in order to make the semiconductor layer efficiently absorb the light from the sun or a white fluorescent lamp, and further electrically has a sheet resistivity value of 300 Ω□ or less, in order to flow an electric current generated by the light in a lateral direction in the semiconductor layer. Examples of the material having such characteristics include a metal oxide such as SnO₂, In₂O₃, ZnO, CdO, CdSnO₄, or ITO (In₂O₃+SnO₂).

(Photovoltaic Element Plate)

The photovoltaic element which is in the state in which the lower electrode layer, the semiconductor layer and the transparent electrode layer have been formed on the substrate, but the current-collecting electrode has not been formed yet, is called “photovoltaic element plate”.

(Etching Line)

The etching line is a linear transparent-electrode-layer-removed-portion provided at the periphery or a to-be-cut portion of the photovoltaic element or the photovoltaic element plate. The purpose of provision of the etching line is to prevent a short circuit occurring between the stainless steel sheet and the transparent electrode layer when cutting a peripheral portion of the photovoltaic element plate from detrimentally affecting the characteristics of the photovoltaic element, and it is preferable that the etching line is formed as thinly as possible.

As a method of forming the etching line, there may be used well-known methods for removing a transparent electrode layer, such as a method of applying an etching paste containing FeCl₃, AlCl₃ or the like by silk screen printing or the like and then effecting heating; a method of electrolyzing the transparent electrode layer in an electrolyte solution to form the etching line; and furthermore, a method of forming the etching line by irradiation with an energy beam such as excimer or second harmonic generation (SHG) of YAG.

(Power-Generating Region)

The power-generating region refers to a region that is surrounded by the etching line.

(Island-Shaped Transparent-Electrode-Layer-Removed-Portion)

The island-shaped transparent-electrode-layer-removed-portion is a transparent-electrode-layer-removed-portion provided separately from the etching line, and is provided at a portion on the light-receiving surface side of the photovoltaic element corresponding to the connection portion of the rear surface side bus-bar electrode and the metal substrate, in order to prevent short circuiting between the substrate and the transparent electrode layer due to degradation (reduction of resistance) of the element at the connection portion from exerting an adverse effect on the power-generating region. Incidentally, the island-shaped transparent-electrode-layer-removed-portion may be provided in the power-generating region either continuously with or separately from the etching line.

By providing the island-shaped transparent-electrode-layer-removed-portion in this manner, the rear surface side bus-bar electrode can be disposed at an arbitrary position regardless of the position at which the bus-bar electrode is disposed. Furthermore, because only the region in which the semiconductor element may be deteriorated due to the connection working of the back side bus-bar electrode can be electrically isolated from the other portion of the transparent electrode layer in the power-generating region, the reliability is improved.

Further, when the island-shaped transparent-electrode-layer-removed-portion in which the substrate is connected to the rear surface side bus-bar electrode is provided between the current-collecting electrodes, even if an insulation member is not particularly provided, the island-shaped transparent-electrode-layer-removed-portion of which the electrical characteristics are not guaranteed, is electrically isolated from the other portion of the transparent electrode layer and the current-collecting electrodes in the power-generating region, so that the component cost can be reduced.

The island-shaped transparent-electrode-layer-removed-portion has only to have such a size as to absorb an alignment error with respect to the size of the connection portion for the rear surface side bus-bar electrode. Providing the island-shaped transparent-electrode-layer-removed-portion separately from the etching line is advantageous in that the rear surface side bus-bar electrode can be provided without making the width of the etching line more than necessary.

As a method of forming the island-shaped transparent-electrode-layer-removed-portion, similarly to the method for forming the etching line, there can preferably be used well-known methods for removing a transparent electrode layer, such as a method of applying an etching paste containing FeCl₃, AlCl₃ or the like by silk screen printing or the like and then effecting heating; a method of electrolyzing the transparent electrode layer in an electrolyte solution to form the etching line; and furthermore a method of forming the etching line by irradiation with an energy beam such as excimer or second harmonic generation (SHG) of YAG. Further, the formation of the etching line and the formation of the island-shaped transparent-electrode-layer-removed-portion may be carried out in either the same step or different steps, and in the case of forming them in different steps, either step may selectively be carried out firstly as needed. Moreover, either of the step of connection between the rear surface 1Q side bus-bar electrode and the substrate, and the step of formation of the island-shaped transparent-electrode-layer-removed-portion may selectively be carried out firstly as needed as long as the both steps are carried out at such a similar position as to absorb the alignment error.

(Rear Surface Side Bus-Bar Electrode)

The rear surface bus-bar electrode is an electrode for assisting the lower electrode layer provided for further decreasing the resistance of the substrate and makes a pair with the current-collecting electrode and the bus-bar electrode. As a material for the rear surface side bus-bar electrode, there is preferably used a metallic material with a low resistance, such as Al, Ag, Pt, Au, Ni, or Cu. The rear surface side bus-bar electrode can be connected to the metal substrate by appropriately using a well-known connection method, such as soldering, brazing, spot-welding, or laser welding or by using a conductive adhesive.

(Insulation Member)

The insulation member is to electrically isolate the island-shaped transparent-electrode-layer-removed-portion from the current-collecting electrode, and therefore needs to have an electrically insulative property. By adopting this structure, because it is possible to electrically isolate from the current-collecting electrode the connection portion between the substrate and the rear surface side bus-bar electrode of which the electrical characteristics are not guaranteed, a photovoltaic element with high reliability can be realized. The insulation member has only to have such a size as to completely cover the island-shaped transparent-electrode-layer-removed-portion, and may be formed in a shape of a wide and long tape and stuck as needed. The insulation member has a structure having an adhesive material disposed on one or both sides of an insulative substrate, where the substrate and adhesive material may be stacked in a form of a plurality of layers.

(Substrate)

Examples of the material constituting the substrate of the insulation member include cellophane, rayon, acetate, polyethylene, polyethylene terephthalate, polyetherketone, fluororesin, polysulfone, unsaturated polyester, epoxy, polyamide, polyimide, polyamide-imide, and polyimide silicone resin. Of these materials for the substrate, polyethylene terephthalate can preferably be used because it not only has good adhesion to an adhesive, a low thermal expansion coefficient and large mechanical strength, but also has a high light transmittance, and does not degrade the power generation characteristics even if it overlaps the power-generating region of the photovoltaic element. Furthermore, when the insulation member is a one-side adhesive tape, in order to increase the bonding strength of the rear surface of the insulation member to the current-collecting electrodes, the rear surface of then insulation member may be subjected to adhesion-improving treatment such as corona treatment.

(Adhesive Material)

As the material constituting the adhesive of the insulation member, there may be included an acrylic adhesive, a rubber adhesive, a silicone adhesive, a polyvinylether adhesive, an epoxy adhesive, a polyurethane adhesive, a nylon adhesive, a polyamide adhesive, an inorganic adhesive, and a composite adhesive. Of these adhesives, those having excellent adhesion, tack, holding power, dielectric strength and moisture resistance are preferably used. Of these adhesives, the acrylic adhesive and the silicone adhesive each have excellent adhesion and holding power and are therefore particularly preferable. As a method of forming the adhesive film, there is included a method of applying an adhesive in a uniform width on a substrate with use of an applicator or the like. Depending on the type of the adhesive used, treatment such as drying, heating, pressurization or light irradiation may be carried out.

(Insulation Member for Bus-Bar Electrode)

The insulation member for the bus-bar electrode needs to have an isolation property for electrically isolating the metal substrate as one electrode of the photovoltaic element or the etching line portion from the bus-bar electrode as the other electrode, and further to mechanically support at least the bus-bar electrode, as needed. The bus-bar electrode may be provided on the non-light-receiving surface of the photovoltaic element for instance, and in this case, the insulation member may be providing ranging from the light-receiving surface of the photovoltaic element to the non-light-receiving surface. The insulation member for the bus-bar electrode has a structure having an adhesive material disposed on both sides of an insulative substrate, and so-called a double-coated tape may be used. Further, the substrate and adhesive material may be stacked in a form of a plurality of layers, and in this case, plural types of the substrates or the adhesive materials may be used. Moreover, as a material for the insulation member for the bus-bar electrode, there are preferably used those substrate and adhesive materials described for the insulation member.

(Current-Collecting Electrode)

The current-collecting electrode is to collect an electric power generated in the semiconductor layer through the transparent electrode layer without loss. It is preferable that the current-collecting electrode is made by using a material with a low resistance to reduce the power loss and is disposed in a shape of a grid or a comb in consideration of the shadow loss. As an electrode having such characteristics, there can be used, for instance, a metallic material such as Al, Ag, Pt, Au, Ni, or Cu; an electroconductive paste having particles of these metals dispersed in a resin; an electroconductive carbon paste; or a composite material thereof.

As a method of forming the current-collecting electrode, there may suitably be used a method of applying an electroconductive paste having metal particles dispersed in a resin or an electroconductive carbon paste by silk screen printing or the like and heating the paste, or a method of applying the paste to a metallic material and then thermocompression bonding the paste to the metallic material with the use of a tool for thermocompression bonding.

(Bus-Bar Electrode)

The bus-bar electrode is a main electrode for further collecting an electric power collected by the current-collecting electrodes, and specifically, is an electrode for taking out the power generated in the semiconductor layer from the photovoltaic element. As a material for the bus-bar electrode, there are preferably be used metallic materials with low resisitivity, such as Al, Ag, Pt, Au, Ni and Cu.

Further, the bus-bar electrode may be provided on either of the light-receiving surface and the non-light-receiving surface depending on the form of the photovoltaic element, and may be disposed outside of the photovoltaic element plate. As a method for electrical connection between the current-collecting electrode and the bus-bar electrode, a method of connecting them with the electroconductive paste used for the current-collecting electrode, or a method of connecting them by soldering or brazing, can be appropriately used.

### EXAMPLES

The present invention will be described in detail below with reference to examples. Here, the examples show representative forms according to the present invention, and the present invention is not limited to the examples.

### Example 1

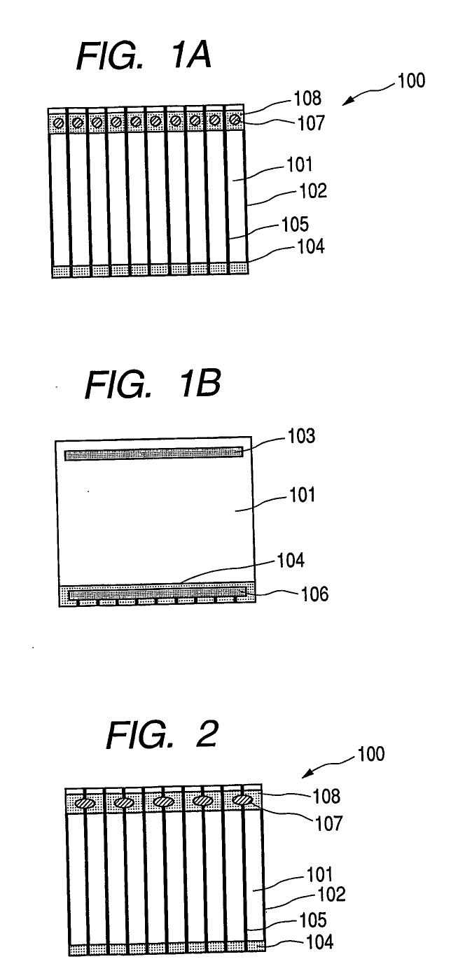

FIGS. 1A and 1B are schematic views for explaining a photovoltaic element according to Example 1 of the present invention. FIG. 1A is a schematic view of a photovoltaic element provided with current-collecting electrodes using metal wires viewed from a light-receiving surface side, and FIG. 1B is a schematic view as viewed from a non-light-receiving surface side.

In FIGS. 1A and 1B, 101 denotes a photovoltaic element plate of 200 mm×250 mm, which has three layers of a lower electrode layer, an amorphous silicon layer having a photovoltaic function and a transparent electrode layer provided on a substrate.

The photovoltaic element plate 101 is formed by sequentially depositing Al and ZnO in a thickness of several hundred nanometers respectively by sputtering right on a stainless steel sheet (substrate) having a thickness of 150 μm for supporting the whole photovoltaic element plate to thereby form a Lower electrode layer; further, sequentially depositing n-type, i-type, p-type, n-type, i-type and p-type layers in this order from the substrate side by plasma CVD to thereby form an amorphous silicon layer; and vapor-depositing In thereon in an O₂ atmosphere by resistive heating to form an indium oxide thin film having a thickness of about 70 nm, as a transparent electrode layer.

Subsequently, the photovoltaic element plate is divided by cutting to an arbitrary size. Then, in order to prevent short circuiting between the stainless steel sheet and the transparent electrode film generated at the periphery of the photovoltaic element plate 101 from exerting an adverse effect on the power-generating region, and to separate the connection portion between the rear surface side bus-bar electrode and the stainless steel sheet provided on the rear surface in the power-generating region, which will be described later, from the other portion of the power-generating region, an etching line 102 is formed by applying an appropriate amount of an etching paste containing FeCl₃, AlCl₃ or the like by screen printing, and then effecting heating followed by cleaning to remove a peripheral portion of the transparent electrode film in a linear shape with a width of 0.3 mm; and concurrently an island-shaped transparent-electrode-layer-removed-portion 107 of a circular shape having a diameter of 4 mm is formed by removing a part of the transparent-electrode-layer at a position between current-collecting electrodes in the power-generating region of the photovoltaic element plate 101. In the region of the thus formed island-shaped transparent-electrode-layer-removed-portion, a connection portion between the photovoltaic element plate 101 and the rear surface side bus-bar electrode 103 is provided as described below.

Then, on the non-light-receiving surface of the photovoltaic element plate 101, a copper foil strip having a width of 5 mm, a length of 200 mm and a thickness of 100 μm as a rear surface side bus-bar electrode 103 is disposed, and in the regions of the island-shaped transparent-electrode-layer-removed-portions 107, the stainless steel sheet and the rear surface side bus-bar electrode 103 are connected to each other. Specifically, at least portions corresponding to the island-shaped transparent-electrode-layer-removed-portions 107 of the rear surface side bus-bar electrode 103 are subjected to the darkening treatment disclosed in Japanese Patent Application Laid-Open No. H11-243224; and then, a laser beam is irradiated from the non-light-receiving surface side of the photovoltaic element plate to the rear surface side bus-bar electrode 103 at positions corresponding to the island-shaped transparent-electrode-layer-removed-portions 107 to fix the rear surface side bus-bar electrode 103 to the stainless steel sheet.

Subsequently, an insulation member 108 is stuck to the light-receiving surface of the photovoltaic element plate 101 so as to completely cover the island-shaped transparent-electrode-layer-removed-portions 107. The insulation member 108 is a transparent one-side adhesive tape having an acrylic adhesive layer of 30 μm in thickness disposed on one side of a substrate of a polyethylene terephthalate film having a width of 6 mm, a length of 200 mm and a thickness of 25 μm. Furthermore, an insulation member 104 for a bus-bar electrode is stuck around an edge portion of the photovoltaic element plate 101 so as to overlap an end portion in 1 mm width of the light-receiving surface side of the photovoltaic element plate 101, ranging from the light-receiving surface to the non-light-receiving surface. The insulation member 104 for the bus-bar electrode is a two-sided adhesive tape of 150 μm in total thickness having acrylic adhesive layers of 50 μm in thickness disposed on both sides of a substrate of a polyimide film having a width of 15 mm, a length of 200 mm and a thickness of 50 μm.

Then, conductive adhesive-coated metal wires 105 consisting of copper wires of 100 μm in diameter coated with a conductive adhesive made of a carbon paste are arranged with every 20 mm interval continuously on the photovoltaic element plate 101, the insulation member 108 and the insulation member 104 for the bus-bar electrode to form current-collecting electrodes. Furthermore, on the insulation member 104 for the bus-bar electrode, a bus-bar electrode 106 is formed as the bus-bar electrode for the current-collecting electrodes. Specifically, the bus-bar electrode 106, which is a copper foil strip having a width of 5 mm, a length of 190 mm and a thickness of 100 μm, is disposed on the insulation member 104, and the whole is heated and pressurized to effect fixation under the conditions of 200° C. and 0.098 MPa (Gauge) for 120 seconds, thus making a photovoltaic element 100.

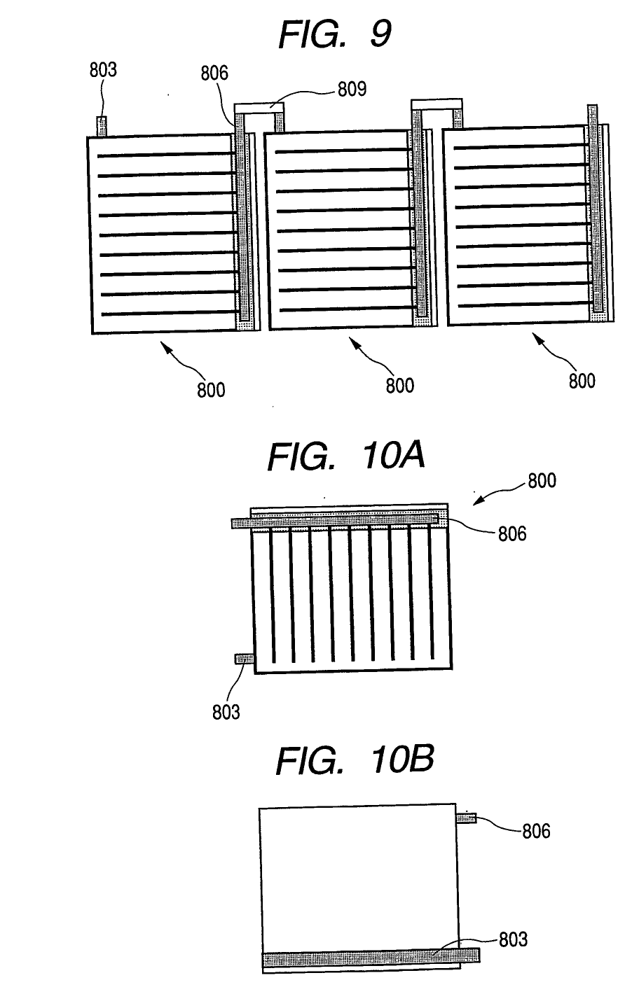

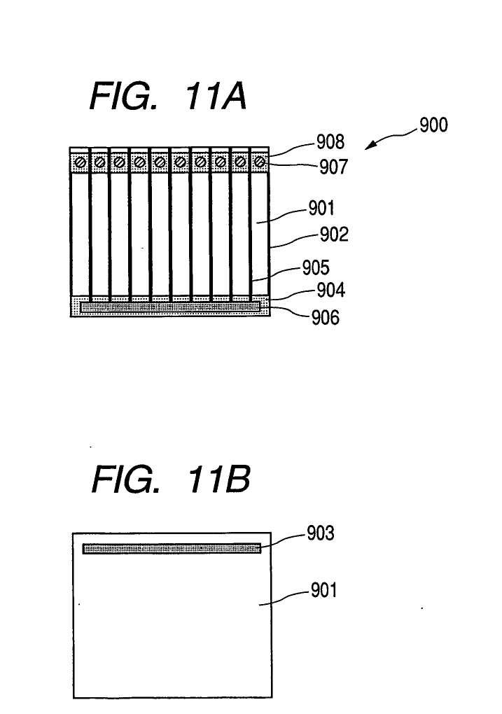

With the photovoltaic element 100 according to the present example, because the rear surface side bus-bar electrode can be provided regardless of the position of the bus bar electrode and the non-electric power-generating region, the rear surface side bus-bar electrode can be disposed at an arbitrary position in the non-light-receiving surface of the photovoltaic element so as to fit the form of a photovoltaic element module. As a result, as shown in FIG. 9, the photovoltaic elements can be easily connected in series in the widthwise direction by using, for example, a connector 809.

Further, because the laser welding method of fixing the rear surface side bus-bar electrode to the photovoltaic element plate is a method of heating a laser-irradiated portion to 800° C. or more to melt that portion thereby performing connection, there is a possibility that the characteristics of the semiconductor element may be deteriorated or diminished by the heating. However, because the island-shaped transparent-electrode-layer-removed-portions are formed in the regions corresponding to the connection portions between the photovoltaic element plate and the rear surface side bus-bar electrode to be electrically isolated from the other portion of the power-generating region and also to be electrically isolated from the current-collecting electrodes, there is no fear of deterioration of the whole photovoltaic element and a reliable element can be provided.

Furthermore, because the photovoltaic element according to the present example can have a ratio of the area of the power-generating region to the area of the light-receiving surface of about 98%, the electrical power output per element can be increased.

Further, as shown in FIG. 2, island-shaped transparent-electrode-layer-removed-portions 107 may be disposed in regions corresponding to connection portions of a rear surface side bus-bar electrode to a photovoltaic element plate regardless of the locations of current-collecting electrodes and then an insulation member 108 may be disposed above the island-shaped transparent-electrode-layer-removed-portions to thereby isolate the island-shaped transparent-electrode-layer-removed-portions from the current-collecting electrodes.

Incidentally, in the present example, the island-shaped transparent-electrode-layer-removed-portion has the diameter of 4 mm, which is a suitable value for removing a region in which the semiconductor layer may be deteriorated when laser welding is performed in accordance with the method such as disclosed in Japanese Patent Application Laid-Open No. 2001-71171. Therefore, when another connection method such as spot welding is employed, the shape and size of the island-shaped transparent-electrode-layer-removed-portion can be appropriately designed.

Furthermore, in the present example, the etching line and the island-shaped transparent-electrode-layer-removed-portions are completely separated from each other. However, they may be integrated with each other as shown in FIG. 3 for instance, and can appropriately be disposed depending on the disposing position of the rear surface side bus-bar electrode, the connecting position of the rear surface side bus-bar electrode to the photovoltaic element plate, or the method of removing a portion of the transparent electrode layer.

Furthermore, although in the present example, the etching line was formed simultaneously with the formation of the island-shaped transparent-electrode-layer-removed-portions, the etching line may be previously formed and the island-shaped transparent-electrode-layer-removed-portions may then be formed in a subsequent step. Specifically, it is possible to form current-collecting electrodes, then dispose the rear surface side bus-bar electrode, irradiate regions between the current-collecting electrodes with a laser beam from the light-receiving surface side to connect the rear surface side bus-bar electrode to the photovoltaic element plate, and then remove those portions of the transparent electrode layer located at and around those portions of the semiconductor layer damaged by the laser irradiation, by means of irradiation with an energy beam such as excimer or second harmonic generation (SHG) of YAG.

### Example 2

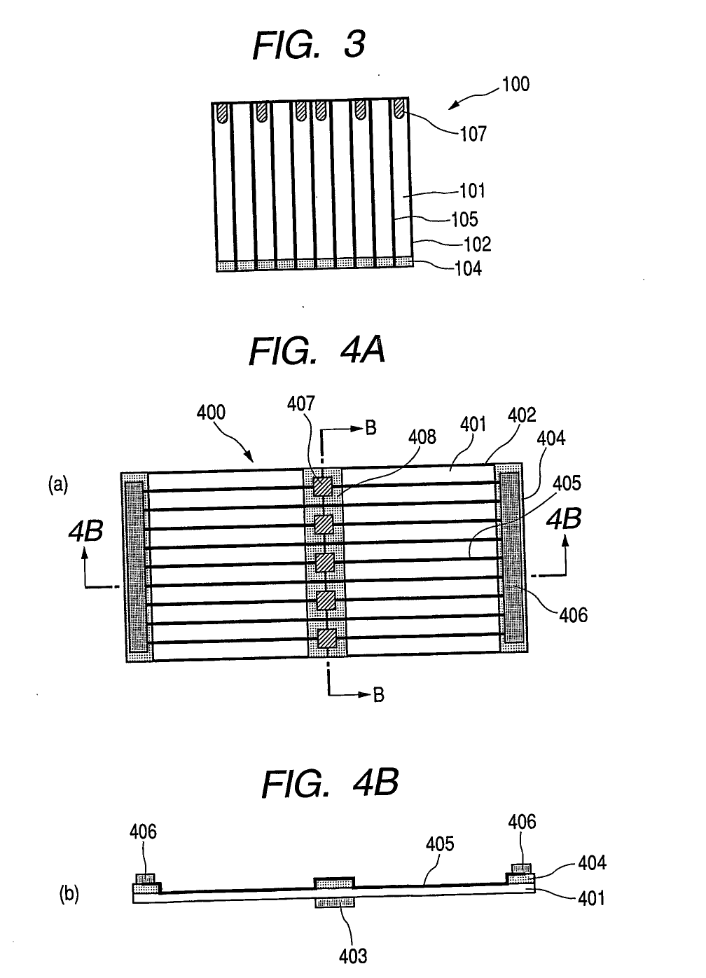

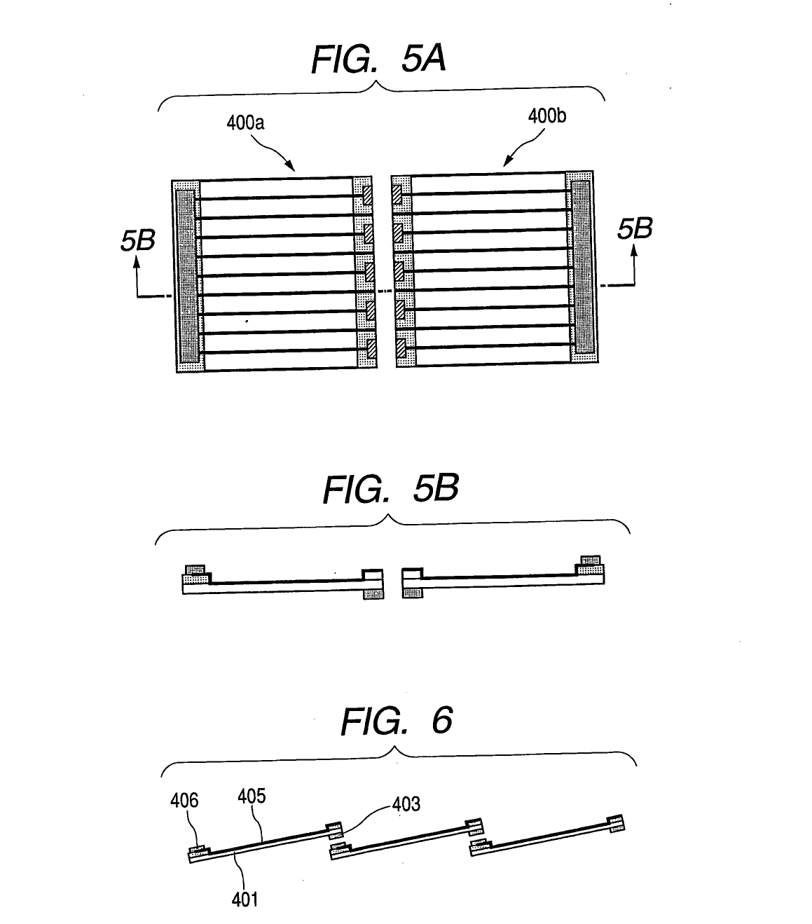

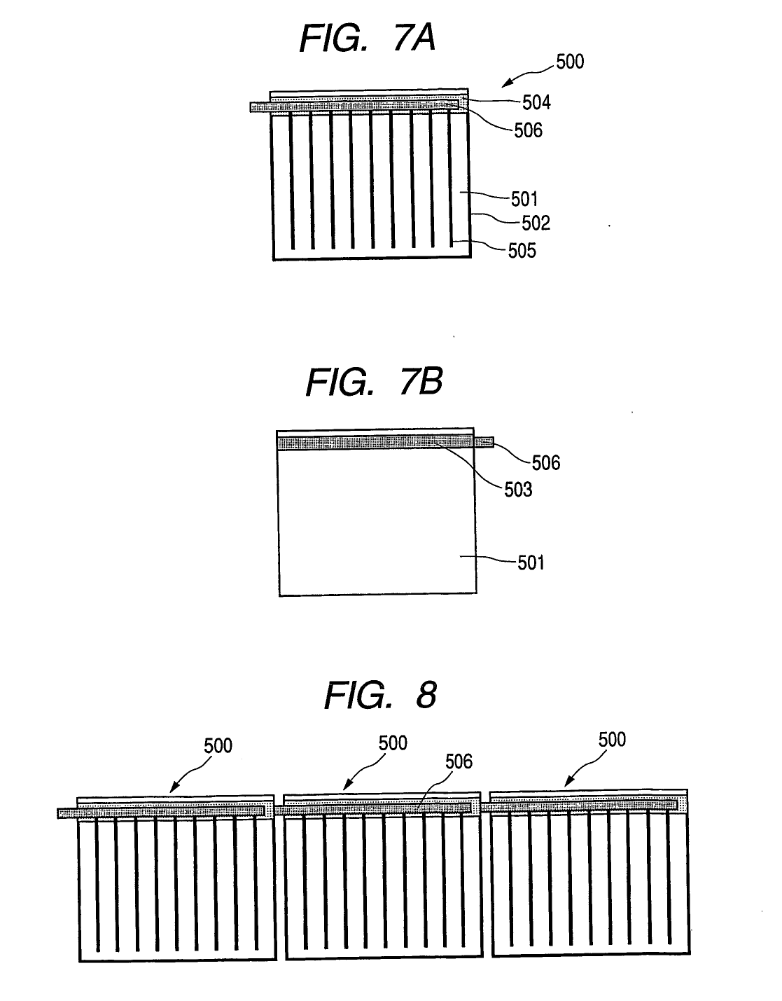

FIG. 4A to FIG. 6 are schematic views for explaining a photovoltaic element according to Example 2 of the present invention. FIG. 4A is a schematic view of the photovoltaic element viewed from a light-receiving surface side; FIG. 4B is a schematic sectional view of taken along line 4B-4B in FIG. 4A; FIG. 5A is a schematic view showing photovoltaic elements obtained by dividing the photovoltaic element of FIG. 4A along line 4B-4B in FIG. 4A; and FIG. 5B is a schematic sectional view taken along line 5B-5B in FIG. 5A.

Example 2 is directed to a photovoltaic element used in a photovoltaic generation system and differs from Example 1 in that two photovoltaic elements are previously made in one photovoltaic element, which is then divided into two to produce the photovoltaic elements, and in the shape of island-shaped transparent-electrode-layer-removed-portions.

In FIGS. 4A and 4B, 401 denotes, similarly to Example 1, a photovoltaic element plate of 200 mm×500 mm, which has three layers of a lower electrode layer, an amorphous silicon layer having a photovoltaic function and a transparent electrode layer provided on a substrate.

When the photovoltaic element plate is divided into the arbitrary size, in order to prevent short circuiting between the substrate and the transparent electrode film generated at the periphery of the photovoltaic element plate 401 from exerting an adverse effect on the power-generating region, and to separate the connection portion between the rear surface side bus-bar electrode and the stainless steel sheet provided on the rear surface in the power-generating region from the other portion of the power-generating region, a part of the transparent electrode film is irradiated with a second harmonic generation (SHG; wave length: 532 nm) of a YAG (yttrium-aluminum-garnet) laser to remove a peripheral portion of the transparent electrode film in a linear shape with a width of 0.2 mm, also to remove a portion of the transparent electrode film at a part for the division (cutting) in a linear shape of a width of 0.5 mm; and further to remove a plurality of portions of the transparent electrode film corresponding to the connection portions with a rear surface side bus-bar electrode 403 to be provided on the rear surface to form a plurality of island-shaped transparent-electrode-layer-removed-portions each having a size of 4 mm×6 mm adjacent to the linear region for the division.

Then, at a location on the rear surface of the photovoltaic element plate 401 corresponding to the linearly removed region for the division, a copper foil strip having a width of 10 mm, a length of 200 mm and a thickness of 100 μm is disposed as the rear surface side bus-bar electrode 403, and the stainless steel sheet and the rear surface side bus-bar electrode 403 are connected at positions on the rear surface of the photovoltaic element plate 401 corresponding to the plurality of island-shaped transparent-electrode-layer-removed-portions 407.

Subsequently, insulation members 408 are stuck to the light-receiving surface of the photovoltaic element plate 401 so as to completely cover the plurality of island-shaped transparent-electrode-layer-removed-portions 407 and also to cover the portion at which the division is to be effected. The insulation member 408 is a transparent one-side adhesive tape having an acrylic adhesive layer of 30 μm in thickness disposed on one side of a substrate of a polyethylene terephthalate film having a width of 12 mm, a length of 200 mm and a thickness of 75 μm.

Furthermore, insulation members 404 for a bus-bar electrode, each of which is a two-sided adhesive tape of 150 μm in total thickness having acrylic adhesive layers of 50 μm in thickness disposed on both sides of a substrate of a polyimide film having a width of 8 mm, a length of 200 mm and a thickness of 50 μm, are stuck to two edge portions of the photovoltaic element plate 401. Then, conductive adhesive-coated metal wires 405 consisting of copper wires of 100 μm in diameter coated with a conductive adhesive made of a carbon paste are arranged with every 20 mm interval continuously on the photovoltaic element plate 401, the insulation members 108 and the insulation members 404 for the bus-bar electrode to form current-collecting electrodes. Furthermore, on the insulation members 404 for the bus-bar electrode, bus-bar electrodes 406, each of which is a copper foil strip having a width of 5 mm, a length of 190 mm and a thickness of 100 μm, are disposed as the bus-bar electrodes for the current-collecting electrodes, and the whole is heated and pressurized to effect fixation under the conditions of 200° C. and 0.098 MPa (Gauge) for 120 seconds, thus producing a photovoltaic element 400.

The thus produced photovoltaic element 400 is divided (separated) along a divisional line B-B shown in FIG. 4A, into two photovoltaic elements 400a and 400b, by using a method, for instance, disclosed in Japanese Patent Application Laid-Open No. H7-321354.

A photovoltaic element module using the above-described photovoltaic element is produced by connecting a plurality of the photovoltaic elements in series or in parallel. In the present example, because the photovoltaic elements 400a and 400b have two opposing output electrodes (bus bar electrode 406 and rear surface side bus-bar electrode 403) attached to the opposite edges on the opposite surfaces of the photovoltaic element plate 401, there can be obtained the technical effect that the elements can be electrically connected in series as shown in FIG. 6. to simplify the series connection step.

This application claims priority from Japanese Patent Application No. 2003-357778 filed on Oct. 17, 2003, which is hereby incorporated by reference herein.

1. A photovoltaic element having at least a photovoltaic layer and a transparent electrode layer deposited on a metal substrate, a portion of the transparent electrode layer being continuously removed at a peripheral part of the metal substrate, wherein an island-shaped transparent-electrode-layer-removed-portion is provided in the transparent electrode layer in a power-generating region surrounded by the removed portion of the transparent electrode layer, a rear surface side bus-bar electrode electrically connected to the metal substrate is disposed on the rear surface side of the metal substrate at the rear of the island-shaped transparent-electrode-layer-removed-portion, and the rear surface side bus-bar electrode is connected to the metal substrate at a portion corresponding to the island-shaped transparent-electrode-layer-removed-portion.

2. The photovoltaic element according to claim 1, wherein the island-shaped transparent-electrode-layer-removed-portion is separate from the removed portion of the transparent electrode layer that surrounds the power-generating region.

3. The photovoltaic element according to claim 1, wherein the island-shaped transparent-electrode-layer-removed-portion is integrated with the removed portion of the transparent electrode layer that surrounds the power-generating region.

4. The photovoltaic element according to claim 1, wherein a current-collecting electrode is disposed through an insulating member on the island-shaped transparent-electrode-layer-removed-portion just over the portion where the rear surface side bus-bar electrode and the metal substrate are connected to each other.

5. The photovoltaic element according to claim 1, wherein a plurality of current-collecting electrodes are provided on the transparent electrode layer, and the island-shaped transparent-electrode-layer-removed-portion just over the portion where the rear surface side bus-bar electrode and the metal substrate are connected to each other is arranged between the current-collecting electrodes.

6. A method of producing a photovoltaic element having at least a photovoltaic layer and a transparent electrode layer deposited on a metal substrate, a portion of the transparent electrode layer being continuously removed at a peripheral part of the metal substrate, the method comprising the steps of:
providing an etching line in the photovoltaic element;
providing an island-shaped transparent-electrode-layer-removed-portion in the transparent electrode layer in a region surrounded by the etching line in the photovoltaic element; and
disposing a rear surface side bus-bar electrode on the rear surface side of the metal substrate at the rear of the island-shaped transparent-electrode-layer-removed-portion and connecting the rear surface side bus-bar electrode to the metal substrate at a portion corresponding to the island-shaped transparent-electrode-layer-removed-portion.

7. The method of producing the photovoltaic element according to claim 6, wherein the step of providing the etching line in the photovoltaic element and the step of providing the island-shaped transparent-electrode-layer-removed-portion are carried out in the same step.

8. The method of producing the photovoltaic element according to claim 6, wherein the step of providing the etching line in the photovoltaic element and the step of providing the island-shaped transparent-electrode-layer-removed-portion are carried out separately from each other.

9. The method of producing the photovoltaic element according to claim 6, wherein at least the step of providing the island-shaped transparent-electrode-layer-removed-portion is carried out prior to the step of connecting the rear surface side bus-bar electrode to the metal substrate.

10. The method of producing the photovoltaic element according to claim 6, wherein at least the step of connecting the rear surface side bus-bar electrode to the metal substrate is carried out prior to the step of providing the island-shaped transparent-electrode-layer-removed-portion.
